(19) United States
(12) Patent Application Publication
(10) Pub. No.: US 2023/0326854 A1
(43) Pub. Date: Oct. 12, 2023

(54) POWER DISTRIBUTION NETWORKS FOR SEMICONDUCTOR CHIP

(71) Applicant: INTERNATIONAL BUSINESS MACHINES CORPORATION, ARMONK, NY (US)

(72) Inventors: Albert M. Chu, Nashua, NH (US); Brent A. Anderson, Jericho, VT (US); Junli Wang, Slingerlands, NY (US); John W. Golz, Hopewell Junction, NY (US); Nicholas Anthony Lanzillo, Wynantskill, NY (US); Lawrence A. Clevenger, Saratoga Springs, NY (US)

(21) Appl. No.: 17/658,487

(22) Filed: Apr. 8, 2022

(51) Int. Cl. H01L 23/528; H01L 21/768; H01L 23/48; H01L 23/522

(52) U.S. Cl. CPC H01L 23/5286; H01L 21/76877; H01L 23/481; H01L 23/5226; H01L 2225/06541

(57) ABSTRACT

Embodiments of present invention provide a semiconductor chip. The semiconductor chip includes a device layer having a first and a second circuit region; a frontside distribution network (FSDN) above the device layer and powering the first circuit region; and a backside distribution network (BSDN) below the device layer and powering the second circuit region, wherein the BSDN is electrically connected to the FSDN through the device layer and the FSDN is electrically connected to the first circuit region through one or more frontside metal layers, and wherein the BSDN is electrically connected to transistors of the second circuit region through the device layer.

### BACKGROUND

The present application relates to manufacturing of semiconductor integrated circuits. More particularly, it relates to a power and signal distribution network for semiconductor chips.

A semiconductor chip contains millions or even billions of transistors that are interconnected and electrically powered to achieve certain device functionality. Current chip technology generally employs wiring made at the frontside of the chip for both power and signal distribution. As a result, the power wiring and signal wiring compete for a same limited wiring area. The ability to rout wire efficiently is quickly becoming a serious challenge for the development of next node technology where the limited wiring area is becoming even scarcer.

As a new technology platform, there is a developing trend of moving the entire power delivery or distribution network to the backside of the chip, leaving the limited real estate of frontside of the chip for signal routing only. This increases not only power delivery efficiency at the backside but also signal routing resources at the frontside.

However, many currently existing and matured circuit blocks, which for example may form various circuit regions in a chip layout, are not suited for or designed to be compatible with backside power delivery because they are mostly, and traditionally, designed for frontside power delivery. A complete revamp or re-design of these circuit blocks to suit for backside power delivery may significantly reduce the efficiency of the semiconductor chip design.

### SUMMARY

Embodiments of present invention provide semiconductor chip. The semiconductor chip includes a device layer having a first and a second circuit region; a frontside distribution network (FSDN) above the device layer and powering the first circuit region; and a backside distribution network (BSDN) below the device layer and powering the second circuit region, wherein the BSDN is electrically connected to the FSDN through the device layer and the FSDN is electrically connected to the first circuit region through one or more frontside metal layers, and wherein the BSDN is electrically connected to transistors of the second circuit region through the device layer.

In one embodiment, the BSDN is electrically connected to a bottom of the second circuit region through one or more through-device-layer-vias (TDLVs), and in one aspect the one or more TDLVs are connected directly to the transistors of the second circuit region.

In another embodiment, the FSDN is connected to the BSDN through one or more connections, the one or more connections being a single power via, a power via stacked on top of a TDLV, or a stack of wires and vias stacked on top of a TDLV.

In one embodiment, the FSDN includes a ring above the first circuit region, the FSDN receives power from the BSDN through an electrical connection made at the ring.

In another embodiment, the FSDN includes a grid above the first circuit region, the FSDN receives power from the BSDN through two or more electrical connections made to the grid.

In one embodiment, the FSDN provides a voltage V2 to the first circuit region, voltage V2 being different from a voltage V1 of the BSDN and being derived from V1 through a voltage regulator in the device layer.

In another embodiment, a voltage V3 derived from a voltage V1 of the BSDN through a voltage regulator in the device layer is provided back to the BSDN and used to power the second circuit region through a TDLV.

### BRIEF DESCRIPTION OF THE DRAWINGS

The present invention will be understood and appreciated more fully from the following detailed description of embodiments of present invention, taken in conjunction with accompanying drawings of which:

FIG. 1 is a schematic illustration of a power and signal distribution network of a semiconductor chip according to one embodiment of present invention;

FIGS. 2A, 2B, and 2C are schematic illustrations of different schemes of connecting a frontside distribution network with a backside distribution network according to some embodiments of present invention;

FIGS. 3A and 3B are simplified top views of the frontside distribution network according to some embodiments of present invention;

FIG. 4 is a schematic illustration of a power and signal distribution network of a semiconductor chip with voltage regulator for a frontside distribution network according to one embodiment of present invention;

FIGS. 5A and 5B are schematic illustrations of a power and signal distribution network of a semiconductor chip with voltage regulator for a backside distribution network according to one embodiment of present invention;

FIG. 6 is a schematic illustration of a power and signal distribution network of a semiconductor chip according to another embodiment of present invention;

FIG. 7 is a schematic illustration of a power and signal distribution network of a semiconductor chip according to yet another embodiment of present invention; and

FIG. 8 is a demonstrative illustration of a flow-chart of a method of manufacturing a strained superlattice according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity or they are embodied in a single physical entity.

### DETAILED DESCRIPTION

In the below detailed description and the accompanying drawings, it is to be understood that various layers, structures, and regions shown in the drawings are both demonstrative and schematic illustrations that are not drawn to scale. In addition, for the ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

Moreover, the same or similar reference numbers are used throughout the drawings to denote the same or similar features, elements, or structures, and thus, a detailed explanation of the same or similar features, elements, or structures may not be repeated for each of the drawings.

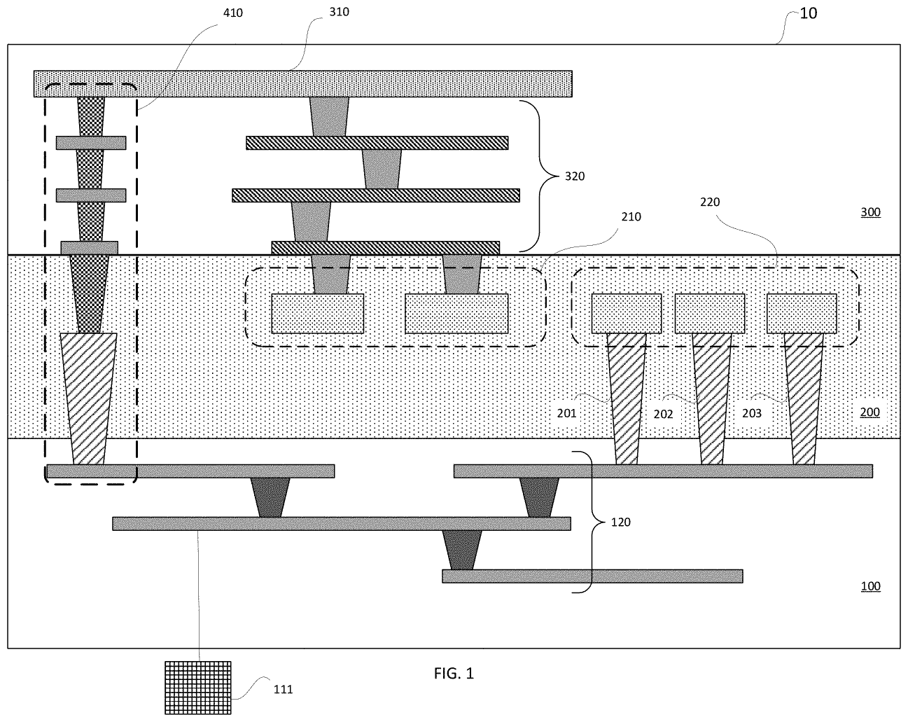

FIG. 1 is a schematic illustration of a power and signal distribution network of a semiconductor chip according to one embodiment of present invention. More particularly, a semiconductor chip 10 may include a device layer 200, which may include for example a front-end-of-line (FEOL) layer and a mid-of-line (MOL) layer; a frontside layer 300, which may include a set of back-end-of-line (BEOL) layers, above the device layer 200; and a backside layer 100 underneath the device layer 200.

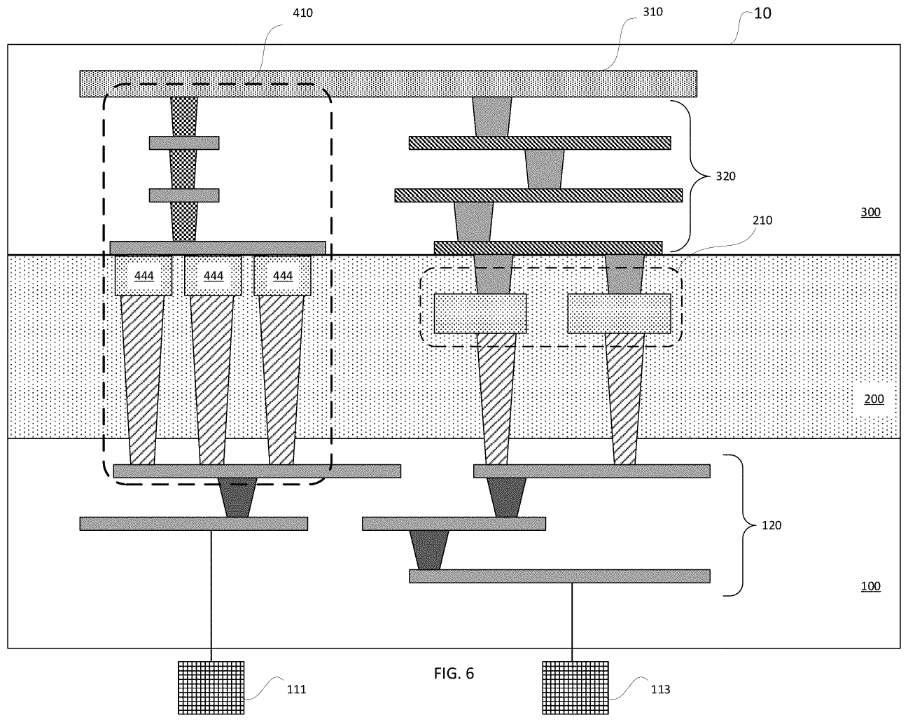

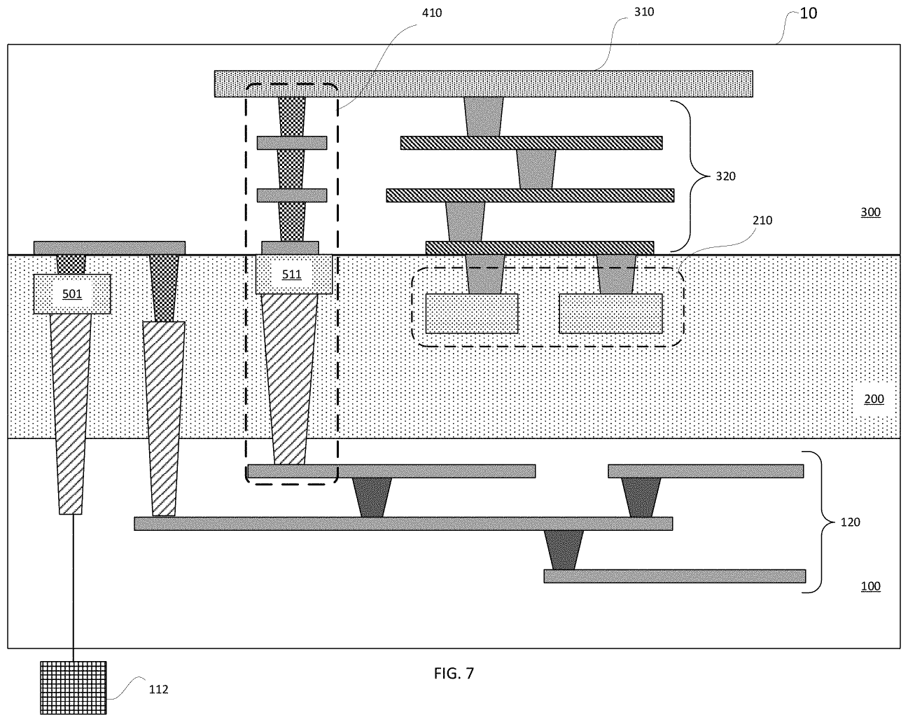

The backside layer 100 may include a backside distribution network (BSDN) 120 and may include one or more connections to some external sources such as external bump pads 111 and 113 (see FIG. 6), for example a C4 bump, that provide power (or voltage) and electrical signals to the BSDN 120. Some other external sources may include for example a clock oscillator 112 (see FIG. 7) or other electrical signals. In addition to power and/or voltage, the BSDN 120 may be able to distribute electrical signals such as clock signals, input/output electric signals to circuit regions in the device layer 200 as being described below in more details.

The device layer 200 may include one or more circuit regions such as, for example, a first circuit region 210 and a second circuit region 220. A circuit region, for example the first circuit region 210, may include one or more transistors such as logic transistors. In one embodiment, a circuit region may be a set of transistors with wiring schemes fabricated according to a pre-existing layout, design, or otherwise a widely used or commercially available design for a functional circuitry, and the circuit region generally requires a frontside powering and/or signaling scheme such as using a frontside distribution network (FSDN) 310. In another embodiment, a circuit region may be a circuit that requires frontside powering and/or signaling scheme such as using the FSDN 310 and may be powered up or receive electrical signals from a backside as well using a backside powering and/or signaling scheme such as using the BSDN 120. In yet another embodiment, a circuit region such as the second circuit region 220, may be powered up and/or receive electric signals only from a backside powering and/or signaling scheme through one or more through-device-layer-vias (TDLVs) such as TDLV 201, TDLV 202 and TDLV 203, and in doing so by using the BSDN 120. For example, the second circuit region 220 may be a transistor or a set of transistors and the transistor or set of transistors may be directly connected to the TDLV 201, TDLV 202, and/or TDLV 203 to receive power and/or other electrical signals from the BSDN 120.

The frontside layer 300 may include the FSDN 310. The FSDN 310 may provide power and/or voltage to one or more circuit regions such as the first circuit region 210 through one or more metal layers such as one or more metal layers 320. The BSDN 120 may be electrically connected to the FSDN 310 through one or more connections such as, for example, a connection 410, as being described below in more details.

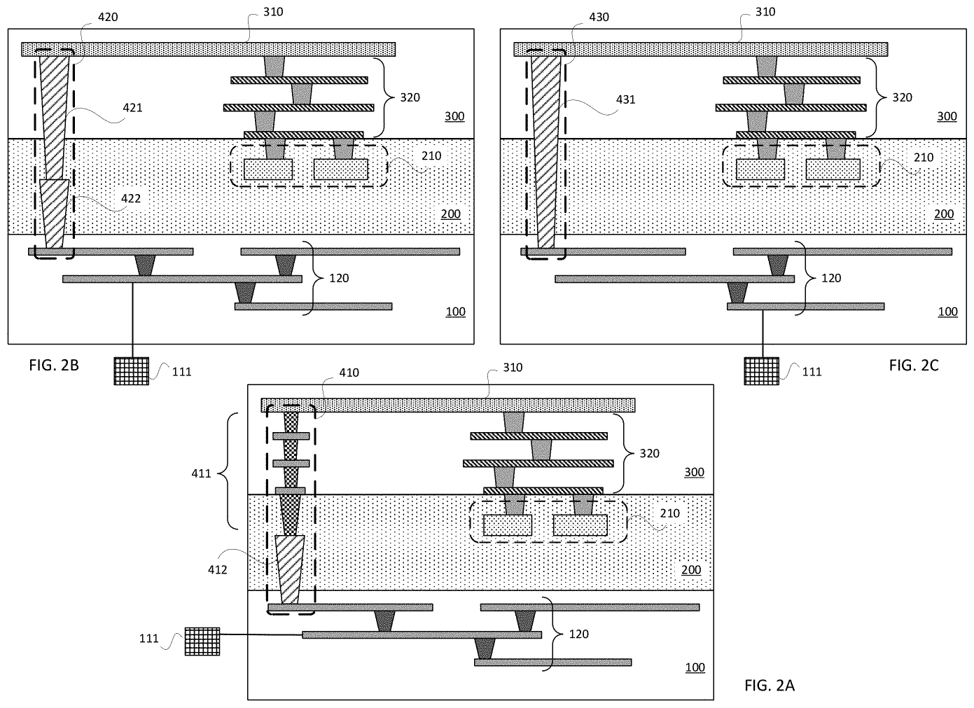

FIGS. 2A, 2B, and 2C are schematic illustrations of different schemes of connecting a frontside distribution network with a backside distribution network according to some embodiments of present invention. More particularly, in one embodiment, FIG. 2A demonstratively illustrates the BSDN 120 being electrically connected to the FSDN 310 through the connection 410. The connection 410 may include a stack or a set of wires and vias 411 stacked on top of a TDLV 412. In another embodiment, FIG. 2B demonstratively illustrates the BSDN 120 being electrically connected to the FSDN 310 through a connection 420. The connection 420 may include a power via 421 being stacked on top of a TDLV 422. The power via 421 may be a skip-via that goes through several levels of metal layers. In yet another embodiment, FIG. 2C demonstratively illustrates the BSDN 120 being electrically connected to the FSDN 310 through a connection 430. The connection 430 may include a single power via 431 that directly connects the FSDN 310 with the BSDN 120. A person skilled in the art will appreciate that embodiments of present invention are not limited in the above aspects. Other types of connections that connects the BSDN 120 with the FSDN 310 may be used and are fully contemplated here.

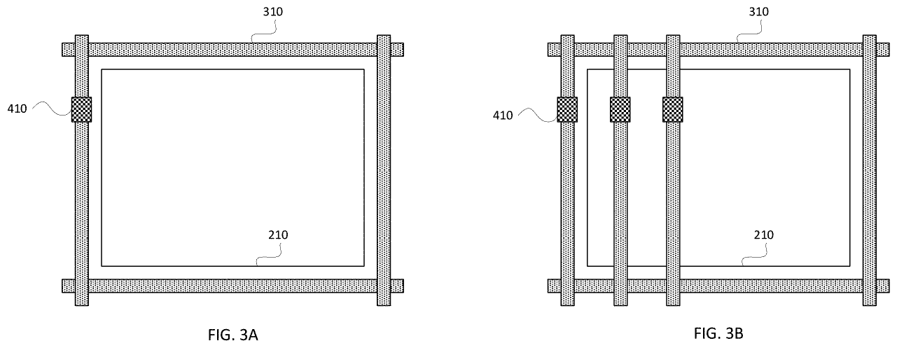

FIGS. 3A and 3B are simplified top views of the frontside distribution network according to some embodiments of present invention. More particularly, corresponding to the FSDN 310 illustrated in FIG. 1, FIG. 3A schematically illustrates a top view of a ring shaped the FSDN 310. The shape of ring may be in a shape of rectangular or square and thus may not necessarily be in a circular or oval shape. The ring shaped FSDN 310 may be made from two or more levels of metal layers (e.g., M7 metal and M8 metal) connected through vias. For example, the two vertically illustrated metal bars may represent two M7 metals and the two horizontally illustrated metal bars may represent two M8 metals. The ring of the FSDN 310 may generally be positioned directly above and over a circuit region such as first circuit region 210. Power or electrical signals may be supplied by the BSDN 120 to the FSDN 310 through the connection 410 made at the ring.

FIG. 3B schematically illustrates a top view of a grid shaped FSDN 310. For example, FSDN 310 may be made of two “horizontal” metal bars, e.g., M8 metals, connected by three or more “vertical” metal bars, e.g., M7 metals. Power or electrical signals may be supplied by the BSDN 120 to the FSDN 310 through multiple connections 410 made at the M7 metals.

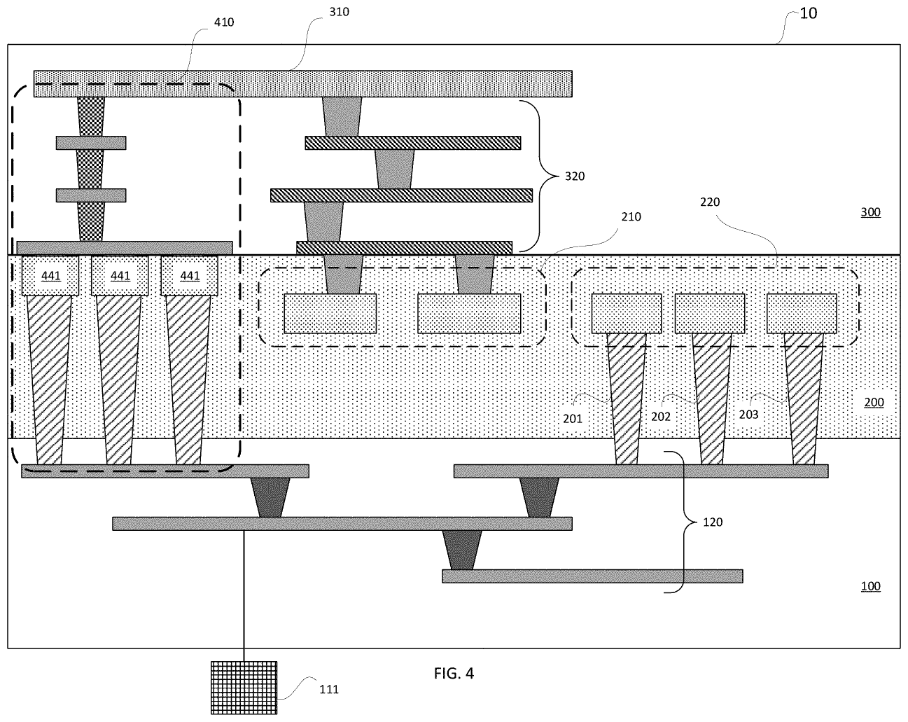

FIG. 4 is a schematic illustration of a power and signal distribution network of a semiconductor chip with voltage regulator for a frontside distribution network according to one embodiment of present invention. More particularly, the FSDN 310 may provide a voltage V2 to the first circuit region 210, where voltage V2 may be different from a voltage V1 available from the BSDN 120. Voltage V1 may come from the external bump pad 111 that provides power connection. According to one embodiment, the connection 410 may include one or more voltage regulators 441 built in the device layer 200. The voltage regulators 441 may derive output voltage V2 from input voltage V1 from the BSDN 120. In other words, voltage regulators 441 may convert input voltage V1 into output voltage V2 and provide output voltage V2 to the FSDN 310. The FSDN 310 may subsequently supply voltage V2 to the first circuit region 210 through the one or more metal layers 320.

FIG. 4 further illustrates that the BSDN 120 may provide voltage V1 directly to the second circuit region 220 at a backside thereof. More particularly, the second circuit region 220 may include one or more transistors and voltage V1 may be directly provided by the BSDN 120 to the one or more transistors through the one or more TDLVs 201, 202, and/or 203.

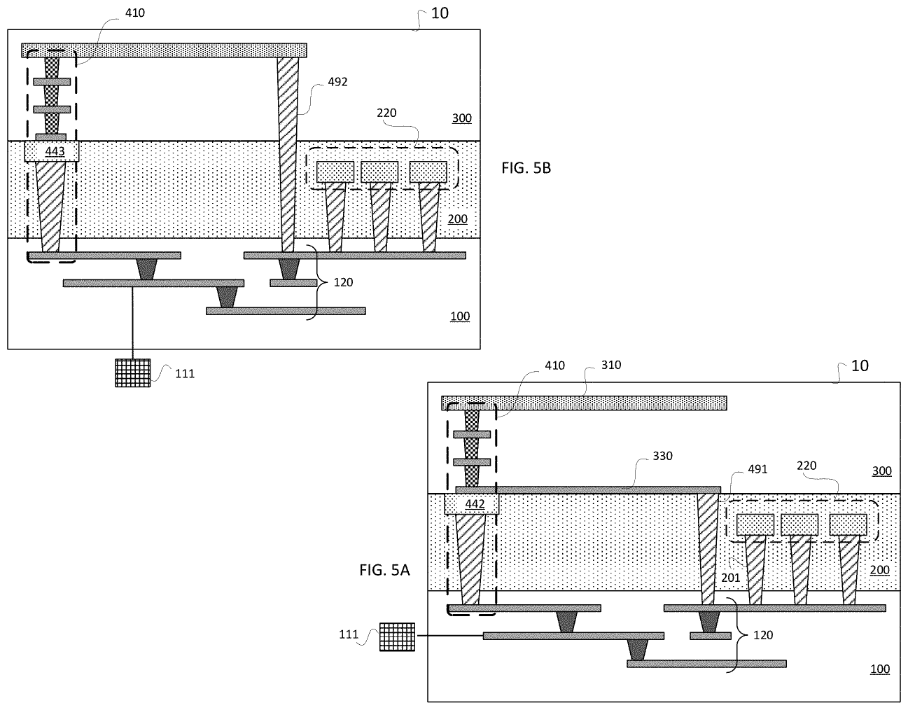

FIGS. 5A and 5B are schematic illustrations of a power and signal distribution network of a semiconductor chip with voltage regulator for a backside distribution network according to one embodiment of present invention. As is demonstratively illustrated in FIG. 1, embodiments of present invention may power or provide electrical signals to a circuit region such as the second circuit region 220 through a backside powering and/or signaling scheme such as the BSDN 120. Moreover, a voltage V3 provided to the second circuit region 220 may be different from a voltage V1 available from the BSDN 120. According to one embodiment of present invention, as illustrated in FIG. 5A, voltage V1 may be provided to a voltage regulator 442 in the device layer 200. The voltage regulator 442 may convert voltage V1 into voltage V3 and subsequently provide voltage V3 back to the BSDN 120 through one of the metal levels 330 and a TDLV 491. Voltage V3 is then used to power transistors of the second circuit region 220 by a part of the BSDN 120 through one or more TDLVs such as the TDLV 201. As is clear from FIG. 5A, transistors of the second circuit region 220 are directly powered up or receive electrical signals directly through the TDLV 201 instead of going through one or more metal layers such as the one or more metal layers 320 as is the case when the FSDN 310 is used in powering the first circuit region 210 (see FIG. 1).

FIG. 5B demonstratively illustrates another scheme of providing voltage V3 to power up the second circuit region 220 at the backside thereof. More particularly, voltage V1 from the BSDN 120 is provided to a voltage regulator 443 in the device layer 200. The voltage regulator 443 converts input voltage V1 into output voltage V3 to supply the FSDN 310. The FSDN 310 then supplies voltage V3 back to the BSDN 120 through, for example, one or more connections such as a connection 492. In one embodiment, the connection 492 may be made similar to the connections 410, 420, and/or 430 demonstratively illustrated in FIGS. 2A-2C.

FIG. 6 is a schematic illustration of a power and signal distribution network of a semiconductor chip according to another embodiment of present invention. More particularly, embodiments of present invention may provide powering the first circuit region 210 from both a frontside and a backside. For example, the BSDN 120 may provide a voltage V1 to the connection 410. V1 may come from the external bump pad 111. The connection 410 may convert voltage V1 into voltage V2 (such as a voltage VDD) through one or more voltage regulators 444. The FSDN 310 receives voltage V2 from the connection 410 and supplies this voltage V2 to the first circuit region 210 through one or more frontside metal layers 320. On the other hand, the BSDN 120 may provide voltage V3 (such as a voltage VSS coming from an external bump pad 113) directly to the first circuit region 210 at a backside thereof, using TDLVs that directly connect to one or more transistors of the first circuit region 210. In one embodiment, V3 from the bump pad 113 may be a ground.

FIG. 7 is a schematic illustration of a power and signal distribution network of a semiconductor chip according to yet another embodiment of present invention. More particularly, the BSDN 120 may provide electrical signals, such as a clock signal and/or input/output signals, to the first circuit region 210 and/or the second circuit region 220 (see FIG. 4). For example, the BSDN 120 may function as a global clock distribution network which receives a clock signal from a clock oscillator 112. The clock signal may be provided by the clock oscillator 112 through an external bump pad and may be provided to a clock buffer 501. The clock buffer 501 may subsequently pass this clock signal down to the BSDN 120, and to a local clock buffer 511 via the BSDN 120. The local clock buffer 511 subsequently provides this clock signal through the FSDN 310 to the first circuit region 210 through the one or more metal layers 320.

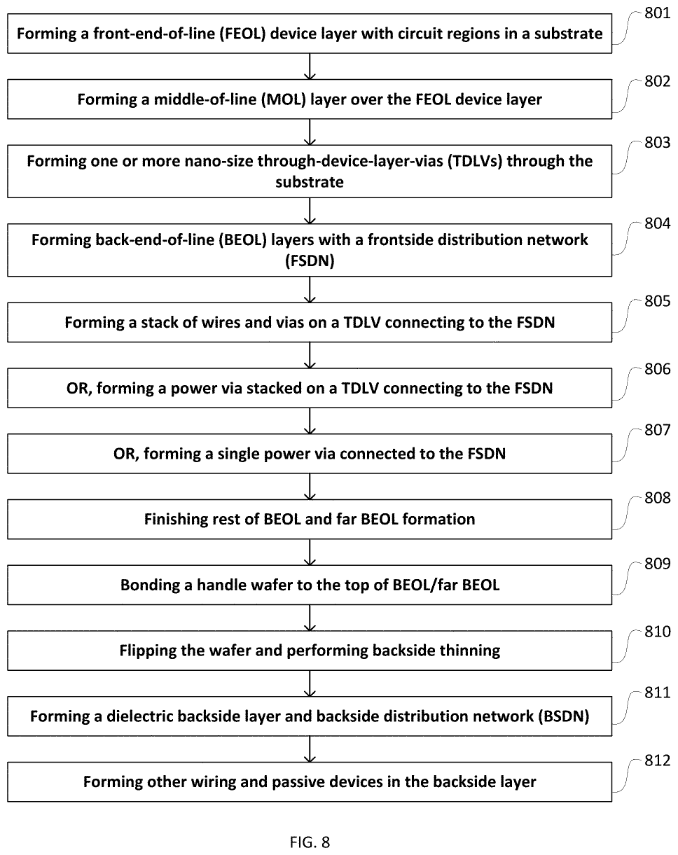

FIG. 8 is a demonstrative illustration of a flow-chart of a method of manufacturing a power and signal distribution network for a semiconductor chip according to embodiments of present invention. More particularly, embodiments of present invention provide (801) forming a front-end-of-line (FEOL) device layer including one or more circuit regions in a semiconductor substrate. The semiconductor substrate may be a bulk silicon substrate or a silicon-on-insulator (SOI) substrate; (802) forming a middle-of-line (MOL) layer over the FEOL device layer; (803) forming one or more TDLVs through the substrate; (804) forming a set of back-end-of-line (BEOL) layers that includes a frontside distribution network (FSDN); (805) forming a stack of wires and vias on top of a TDLV that connects to the frontside distribution network, or (806) forming a power via stacked on top of a TDLV that connects to the frontside distribution network, or (807) forming a single power via that connects to the frontside distribution network; and (808) finishing forming rest of BEOL layers and far BEOL (FBEOL) at the front side of the semiconductor chip. Upon finishing forming the frontside, embodiments of present invention continue with forming the backside of the semiconductor chip. More particularly, embodiments of present invention provide (809) bonding a handle wafer to the top of the BEOL and/or FBEOL layers; (810) flipping the wafer and performing backside thinning of the semiconductor chip; (811) depositing dielectric materials to form a dielectric backside layer including forming a backside distribution network (BSDN); and (812) subsequently finishing forming other wiring and passive devices in the backside layer.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Although exemplary embodiments have been described herein with reference to the accompanying figures, it is to be understood that the invention is not limited to those precise embodiments, and that various other changes and modifications may be made therein by one skilled in the art without departing from the scope of the appended claims.

It is to be understood that the various layers, structures, and/or regions described above are not necessarily drawn to scale. In addition, for ease of explanation one or more layers, structures, and regions of a type commonly used to form semiconductor devices or structures may not be explicitly shown in a given illustration or drawing. This does not imply that any layers, structures, and regions not explicitly shown are omitted from the actual semiconductor structures.

Furthermore, it is to be understood that the embodiments discussed herein are not limited to the particular processing steps shown and described herein. In particular, with respect to semiconductor processing steps, it is to be emphasized that the descriptions provided herein are not intended to encompass all of the processing steps that may be used to form a functional semiconductor integrated circuit device. Rather, certain processing steps that are commonly used in forming semiconductor devices, such as, for example, wet cleaning and annealing steps, are purposefully not described herein for economy of description.

Terms such as “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount.

In some embodiments, the above-described techniques are used in connection with manufacture of semiconductor integrated circuit devices that illustratively include, by way of non-limiting example, CMOS devices, MOSFET devices, and/or FinFET devices, and/or other types of semiconductor integrated circuit devices that incorporate or otherwise utilize CMOS, MOSFET, and/or FinFET technology.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other higher level carrier) or in a multichip package (such as a ceramic carrier that has either or both surface interconnections or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While certain features of the invention have been illustrated and described herein, many modifications, substitutions, changes, and equivalents will now occur to those of ordinary skill in the art. Such changes, modification, and/or alternative embodiments may be made without departing from the spirit of present invention and are hereby all considered within the scope of present invention. It is, therefore, to be understood that the appended claims are intended to cover all such modifications and changes as fall within the spirit of the invention.

What is claimed is:

1. A semiconductor chip comprising:
a device layer having a first and a second circuit region;
a frontside distribution network (FSDN) above the device layer and powering the first circuit region; and
a backside distribution network (BSDN) below the device layer and powering the second circuit region,
wherein the BSDN is electrically connected to the FSDN through the device layer; the FSDN is electrically connected to the first circuit region through one or more frontside metal layers; and the BSDN is electrically connected to one or more transistors of the second circuit region through the device layer.

2. The semiconductor chip of claim 1, wherein the BSDN is electrically connected to a bottom of the second circuit region through one or more through-device-layer-vias (TDLVs).

3. The semiconductor chip of claim 2, wherein the one or more TDLVs are connected directly to the one or more transistors of the second circuit region.

4. The semiconductor chip of claim 1, wherein the BSDN is connected to the FSDN through one or more connections, the one or more connections being a single power via, a power via stacked on top of a through-device-layer-via (TDLV), or a stack of wires and vias stacked on top of a TDLV.

5. The semiconductor chip of claim 1, wherein the FSDN comprises a ring above the first circuit region, the FSDN receives power from the BSDN through an electrical connection made at the ring.

6. The semiconductor chip of claim 1, wherein the FSDN comprises a grid above the first circuit region, the FSDN receives power from the BSDN through two or more electrical connections made to the grid.

7. The semiconductor chip of claim 1, wherein the FSDN provides a voltage V2 to the first circuit region, the voltage V2 being different from a voltage V1 of the BSDN and being derived from the voltage V1 through a voltage regulator in the device layer.

8. The semiconductor chip of claim 1, wherein a voltage V3 derived from a voltage V1 of the BSDN through a voltage regulator in the device layer is provided back to the BSDN and used to power the second circuit region through a through-device-layer-via (TDLV).

9. The semiconductor chip of claim 8, wherein the FSDN provides the voltage V3 back to the BSDN.

10. The semiconductor chip of claim 8, wherein the voltage regulator provides the voltage V3 back to the BSDN through the device layer without going through the FSDN.

11. The semiconductor chip of claim 1, wherein the FSDN provides a voltage V2 to the first circuit region and the BSDN provides a voltage V1 directly to transistors of the first circuit region through one or more through-device-layer-vias (TDLVs), wherein the voltage V2 being different from the voltage V1 and being derived from the voltage V1 through a voltage regulator in the device layer.

12. The semiconductor chip of claim 4, wherein the BSDN receives a global clock signal from an external clock oscillator and pass the global clock signal to the FSDN through the one or more connections, the FSDN supplies the global clock signal to the first circuit region.

13. A semiconductor chip comprising:
a device layer having at least a first and a second circuit region;
a frontside distribution network (FSDN) above the device layer; and
a backside distribution network (BSDN) below the device layer,
wherein the BSDN is electrically connected to the FSDN through one or more connections; the FSDN is electrically connected to and powers the first circuit region; and the BSDN is directly connected to transistors of the second circuit region electrically through one or more through-device-layer-vias (TDLVs).

14. The semiconductor chip of claim 13, wherein the one or more connections is a single power via, a power via stacked on top of a TDLV, or a stack of wires and vias stacked on top of a TDLV.

15. The semiconductor chip of claim 13, wherein the FSDN comprises a ring above the first circuit region, the ring comprising two or more metal layers connected through vias.

16. The semiconductor chip of claim 13, wherein the FSDN comprises a grid above the first circuit region, the FSDN receives power from the BSDN through the one or more connections, wherein the one or more connection includes two or more connections made to the grid.

17. A semiconductor chip comprising:
a backside distribution network (BSDN);
a device layer over the BSDN, the device layer having a first and a second circuit region;
a frontside distribution network (FSDN) over the device layer,
wherein the BSDN is electrically connected to the FSDN through one or more voltage regulators in the device layer to power the first circuit region; and wherein the BSDN is directly connected to transistors of the second circuit region through at least one through-device-layer-via (TDLV).

18. The semiconductor chip of claim 17, wherein the FSDN provides a voltage V2 to the first circuit region, the voltage V2 being different from a voltage V1 of the BSDN and being derived from the voltage V1 through the one or more voltage regulators.

19. The semiconductor chip of claim 17, wherein a voltage V3 derived from a voltage V1 of the BSDN through the one or more voltage regulators is provided back to the BSDN and used to power the second circuit region through the at least one TDLV.

20. The semiconductor chip of claim 17, wherein the BSDN receives a clock signal from an external clock oscillator and pass the clock signal, via the FSDN, to the first circuit region.
